(19) United States
(12) Patent Application Publication
(10) Pub. No.: US 2026/0011547 A1
(43) Pub. Date: Jan. 8, 2026

(54) METHODS OF DEPOSITING SILICON-CONTAINING FILMS FOR SEMICONDUCTOR DEVICES

(71) Applicant: Applied Materials, Inc., Santa Clara, CA (US)

(72) Inventors: Zachary J. Devereaux, Webberville, MI (US); Thomas Joseph Knisley, Livonia, MI (US); Bhaskar Jyoti Bhuyan, San Jose, CA (US); Mark Saly, Santa Clara, CA (US); Akhil Singhal, Portland, OR (US)

(73) Assignee: Applied Materials, Inc., Santa Clara, CA (US)

(21) Appl. No.: 18/764,525

(22) Filed: Jul. 5, 2024

(51) Int. Cl. H01L 21/02; C23C 16/40; C23C 16/455

(52) U.S. Cl. CPC H01L 21/02164; C23C 16/402; C23C 16/45536; H01L 21/02211; H01L 21/02216; H01L 21/02271

(57) ABSTRACT

Methods of depositing silicon-containing films by plasma-enhanced vapor deposition, e.g., plasma-enhanced chemical vapor deposition (PECVD) or plasma-enhanced atomic layer deposition (PEALD), are disclosed. Exemplary methods include exposing a substrate in a processing system to a silicon-containing precursor; exposing the substrate to an oxygen-containing reagent; and exposing the substrate to a plasma of an inert gas.

### TECHNICAL FIELD

Embodiments of the disclosure generally relate to the field of semiconductor device manufacturing. More particularly, embodiments of the disclosure are directed to methods of depositing silicon-containing films by plasma-enhanced vapor deposition.

### BACKGROUND

Silicon-containing films, such as, for example, silicon nitride (SiN), silicon oxide (SiO), silicon carbonitride (SiCN), silicon oxycarbide (SiOC), and silicon carboxynitride (SiCON) films have attractive dielectric material properties. These films have been proposed and tested for applications from front-end of line (FEOL) to back-end of line (BEOL) processes and parts of semiconductor devices and microelectronic devices. Generally, FEOL refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a semiconductor wafer.

Low temperature, e.g., less than or equal to 600° C., vapor deposition of silicon-containing films is used in many semiconductor applications. Without intending to be bound by any particular theory, it is thought that many of these films are deposited by plasma-enhanced chemical vapor deposition (PECVD) or plasma-enhanced atomic layer deposition (PEALD) due to poor film quality when deposited by low temperature thermal processes, e.g., thermal ALD processes. In some cases, a silicon-containing film does not form at all at low temperatures in thermal ALD processes.

PEALD film quality, for example, varies based on the surface (e.g., substrate) on which the film is deposited. In particular, it has been found that PEALD film quality varies based on the geometry of the substrate, and areas that are harder to treat with plasma species may receive less plasma treatment and have poorer film quality.

It has also been found that current PEALD approaches, e.g., exposure to silicon-containing precursor, purge, exposure to O₂/Ar plasma, purge, to form a silicon oxide (SiO₂) film, oxidizes the underlying substrate, which can be detrimental to device performance. With decreasing technology nodes, depositing silicon oxide (SiO₂) films in a bottom-up fashion for shallow trench isolation (STI) applications, for example, remains a challenge.

Accordingly, there is a need for PEALD processes for depositing silicon-containing films at decreasing technology nodes without oxidizing the underlying substrate.

### SUMMARY

One or more embodiments of the disclosure are directed to a method of depositing a silicon-containing film. The method comprises exposing a substrate in a processing system to a silicon-containing precursor; exposing the substrate to an oxygen-containing reagent; and exposing the substrate to a plasma of an inert gas, wherein exposing the substrate to the silicon-containing precursor and exposing the substrate to the oxygen-containing reagent are each performed without the use of plasma.

Additional embodiments of the disclosure are directed to a method of deposition a silicon-containing film. The method comprises exposing a substrate in a processing system to a silicon-containing precursor comprising hexachlorodisilane or bis(diethylamino)silane; exposing the substrate to an oxygen-containing reagent comprising water, ethanol, or tert-butanol; and exposing the substrate to a plasma comprising argon (Ar), wherein exposing the substrate to the silicon-containing precursor and exposing the substrate to the oxygen-containing reagent are each performed without the use of plasma, the substrate comprises at least one feature having a bottom surface and two sidewalls, the at least one feature has an aspect ratio in a range of 1:1 to 100:1, and the silicon-containing film is deposited to fill the at least one feature in a bottom-up fashion.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of the present disclosure and are therefore not to be considered limiting of its scope, for the disclosure may admit to other equally effective embodiments.

FIG. 1 illustrates a process flow diagram of a method of depositing a silicon-containing film according to one or more embodiments of the disclosure;

FIG. 2A illustrates a cross-sectional schematic view of a substrate according to one or more embodiments of the disclosure;

FIG. 2B illustrates a cross-sectional schematic view of a substrate according to one or more embodiments of the disclosure; and

FIG. 2C illustrates a cross-sectional schematic view of a substrate according to one or more embodiments of the disclosure.

To facilitate understanding, identical reference numerals have been used, where possible, to designate identical elements that are common to the Figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of +15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the Figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “some embodiments,” “certain embodiments,” “one or more embodiments,” or “an embodiment” means that a particular feature, structure, material, or characteristic described in connection with the embodiment is included in at least one embodiment of the disclosure. Thus, the appearances of the phrases such as “in one embodiment,” “in some embodiments,” “in certain embodiments,” “in one or more embodiments,” or “in an embodiment” in various places throughout this specification are not necessarily referring to the same embodiment of the disclosure. Furthermore, the particular features, structures, materials, or characteristics may be combined in any suitable manner in one or more embodiments.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate on which processing can be performed include materials such as silicon, silicon oxide, strained silicon, silicon on insulator (SOI), carbon doped silicon oxides, amorphous silicon, doped silicon, germanium, silicon germanium, gallium arsenide, and any other materials such as a metallic material, metal nitrides, metal alloys, and other conductive materials, depending on the application.

Substrates include, without limitation, semiconductor wafers. Substrates may include FEOL channel materials, such as, for example, gate contacts, silicon germanium (SiGe) and/or epi contacts). Substrates may include BEOL metals, such as, for example, copper, cobalt, tungsten, molybdenum, ruthenium, tantalum, titanium, nitrides thereof, and/or alloys thereof.

Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, vias which have one or more sidewall extending into the substrate to a bottom, and slot vias.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used in this specification and the appended claims, the terms “precursor”, “reactant”, “reactive gas” and the like are used interchangeably to refer to any gaseous species that can react with the substrate surface.

As used herein, “chemical vapor deposition” refers to a process in which a substrate surface is exposed to precursors and/or reactants simultaneously or substantially simultaneously. As used herein, “substantially simultaneously” refers to either co-flow or where there is overlap for a majority of exposures of the precursors and/or reactants.

Plasma-enhanced chemical vapor deposition (PECVD) methods add a plasma exposure to traditional CVD methods. In some PECVD methods, an inert gas source is provided as the plasma. Embodiments described herein in reference to a PECVD process can be carried out using any suitable deposition system.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially.

In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, the term “thermal process(es)” refers to a deposition technique that does not involve the use of plasma. As used herein, the term “plasma” refers to a composition have ionically charged species and uncharged neutral and radical species. As used herein, a “radical-rich plasma” comprises greater than 50% radical species.

Plasma-enhanced atomic layer deposition (PEALD) methods add a plasma exposure to traditional ALD methods. In some PEALD methods, an inert gas source is provided as the plasma. The primary benefit of PEALD methods is the relatively low substrate temperature, e.g., less than or equal to 600° C., during processing. Embodiments described herein in reference to a PEALD process can be carried out using any suitable deposition system.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Embodiments of the disclosure are directed to methods of depositing silicon-containing films by plasma-enhanced vapor deposition. One or more embodiments are directed to methods of depositing silicon-containing films by plasma-enhanced chemical vapor deposition (PECVD). One or more embodiments are directed to methods of depositing silicon-containing films by plasma-enhanced atomic layer deposition (PEALD).

One or more layers deposited on the substrate or substrate surface by atomic layer deposition (ALD) or plasma-enhanced atomic layer deposition (PEALD) are conformal. As used herein, as will be understood by the skilled artisan, a layer which is “conformal” or “conformally deposited” refers to a layer where the thickness is about the same throughout. A layer/film which is conformal varies in thickness by less than or equal to about 5%, 2%, 1% or 0.5%.

The skilled artisan will recognize that the use of a molecular formula, such as, for example, silicon oxide (SiₓO_{y}) does not imply specific stoichiometric relation between the elements but merely the identity of the major components of the film. In some embodiments, the major composition of the specified film (i.e., the sum of the atomic percent of the specified atoms) is greater than or equal to about 95%, 98%, 99%, 99.5%, or 99.9% of the film, on an atomic basis. In one or more embodiments, as an example, the silicon-containing film comprises silicon oxide (SiₓO_{y}) in the form of SiO₂.

One or more embodiments are directed to methods of depositing silicon-containing films by plasma-enhanced chemical vapor deposition (PECVD) comprising exposing a substrate in a processing system to a silicon-containing precursor; exposing the substrate to an oxygen-containing reagent; and exposing the substrate to a plasma of an inert gas. One or more of the exposures (e.g., the exposure to the silicon-containing precursor, the exposure to the oxygen-containing reactant, or the exposure to the plasma of the inert gas) may occur simultaneously or substantially simultaneously. In some embodiments, each of the exposures (e.g., the exposure to the silicon-containing precursor, the exposure to the oxygen-containing reactant, and the exposure to the plasma of the inert gas) occur simultaneously or substantially simultaneously.

In one or more embodiments, the substrate is exposed to the silicon-containing precursor and the oxygen-containing reagent simultaneously or substantially simultaneously while the plasma of the inert gas is turned on. In one or more embodiments, the substrate is exposed to the silicon-containing precursor, followed by exposing the substrate to the oxygen-containing reagent and the plasma of the inert gas simultaneously or substantially simultaneously.

In one or more embodiments, the substrate is exposed to the silicon-containing precursor and the plasma of the inert gas simultaneously or substantially simultaneously, followed by exposing the substrate to the oxygen-containing reagent and the plasma of the inert gas simultaneously or substantially simultaneously.

In one or more embodiments, the substrate is exposed to the oxygen-containing reagent and the plasma of the inert gas simultaneously or substantially simultaneously, followed by exposing the substrate to the silicon-containing precursor and the plasma of the inert gas simultaneously or substantially simultaneously.

One or more embodiments are directed to methods of depositing silicon-containing films by plasma-enhanced atomic layer deposition (PEALD) comprising exposing a substrate in a processing system to a silicon-containing precursor; purging the substrate; exposing the substrate to an oxygen-containing reagent; purging the substrate; exposing the substrate to a plasma of an inert gas; and purging the substrate.

It has been found that current PEALD approaches, e.g., exposure to silicon-containing precursor, purge, exposure to O₂/Ar plasma, purge, to form a silicon oxide (SiO₂) film, oxidizes the underlying substrate, which can be detrimental to device performance. It is thought that these current PEALD approaches oxidize the underlying substrate due to the O₂/Ar plasma having a large amount of activated oxygen species, such as oxygen radicals and oxygen ions.

Embodiments of the disclosure advantageously provide methods of depositing silicon-containing films, e.g., silicon oxide (SiO₂) films, substantially without oxidizing or without oxidizing, the underlying substrate. That is, in one or more embodiments, advantageously, the reaction of the silicon-containing precursor, the oxygen-containing reagent and the plasma of the inert gas in accordance with the methods described herein does not oxidize the underlying substrate. As described herein, an amount of substrate oxidation (Å) can be expressed as the average thickness of an oxide film in Å on the substrate. In one or more embodiments, advantageously, the reaction of the silicon-containing precursor, the oxygen-containing reagent and the plasma of the inert gas in accordance with the methods described herein provides a reduced amount of oxidation of the underlying substrate compared to current PEALD approaches.

In particular, it has been advantageously found that the plasma comprising oxygen (O₂) and argon (Ar) of current PEALD approaches produces a greater percentage of silicon oxidation than, as described in one or more embodiments herein, an alcohol, such as ethanol or tert-butanol with a plasma comprising argon (Ar).

In one or more embodiments, the methods described herein are part of a gap fill process. The methods described herein may be utilized with any device nodes, but may be particularly advantageous in device nodes of about 25 nm or less, for example about 5 nm to about 25 nm. In some embodiments, a silicon-containing film is deposited on a dielectric surface with one or more high aspect ratio structures, including vertically extending features and/or laterally extending features, and the silicon-containing film in the features forms interconnects through which current flows. It will be appreciated by the skilled artisan that the methods described herein that are part of a gap fill process can include one or more subsequent operations after forming the silicon-containing film, such as, for example, filling the gap with a conductive material, to form an interconnect, and that the one or more subsequent operations can be performed without undue experimentation.

Embodiments of the disclosure advantageously provide methods of depositing silicon-containing films in a bottom-up fashion in a feature. In one or more embodiments, the silicon-containing films are advantageously deposited in a bottom-up fashion to fill the feature. In one or more embodiments, the silicon-containing films are advantageously deposited in a bottom-up fashion for shallow trench isolation (STI) applications.

In one or more embodiments, the methods described herein are representative of a reactive ion deposition process. As used herein, a “reactive ion deposition process” refers to ion-deposition sputtering wherein a reactive gas is supplied during the sputtering to react with the ionized material being sputtered, producing an ion-deposition-sputtered compound containing the reactive gas element. In one or more embodiments, the reactive gases supplied are the silicon-containing precursor and the oxygen-containing reagent, respectively, and the ionized material is the plasma of the inert gas.

Some embodiments advantageously provide the ability to control the composition of silicon-containing films. Some embodiments advantageously provide methods of depositing silicon-containing films on a substrate comprising at least one feature, e.g., at least one vertically extending feature and/or at least one laterally extending feature. Some embodiments advantageously provide methods of depositing silicon-containing films that are useful for FEOL and BEOL processes and parts.

One or more embodiments are directed to methods of depositing silicon-containing films in high aspect ratio structures, e.g., in memory devices or logic devices (at less than 10 nm technology nodes), including, but not limited to, NAND, 3D-NAND, dynamic random-access memory (DRAM) cells, 3D DRAM, Fin field effect transistors (FinFET), gate-all-around (GAA) transistors, and the like.

As used herein, a “high aspect ratio” structure has an aspect ratio greater than or equal to about 20:1, such as, for example, in a range of from 50:1 to 150:1. In some embodiments, the silicon-containing film is conformally deposited on the high aspect ratio feature.

Some embodiments advantageously provide methods of depositing silicon-containing films having improved film quality. There are multiple metrics used to measure the silicon-containing film quality. One of the most common metrics used to measure the silicon-containing film quality is the wet etch rate (WER) of the deposited film under dilute hydrofluoric (HF) acid etch solution, such as dilute HF 100:1. Embodiments of the disclosure advantageously provide silicon-containing films that have a reduced etch amount in Angstroms (Å) using dilute HF 100:1, which represents an improved wet etch rate, compared to current PEALD approaches. The wet etch rate ratio (WERR) is a metric given that compares the WER of the deposited film relative to that of thermal silicon dioxide, which is about 25 Å/min.

The embodiments of the disclosure are described by way of the Figures, which illustrate processes, substrates, and apparatuses in accordance with one or more embodiments of the disclosure. The processes and resulting substrates shown are merely illustrative of the disclosed processes, and the skilled artisan will recognize that the disclosed processes are not limited to the illustrated applications.

In the following description, numerous specific details are set forth in order to provide a thorough understanding of the embodiments of the disclosure. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

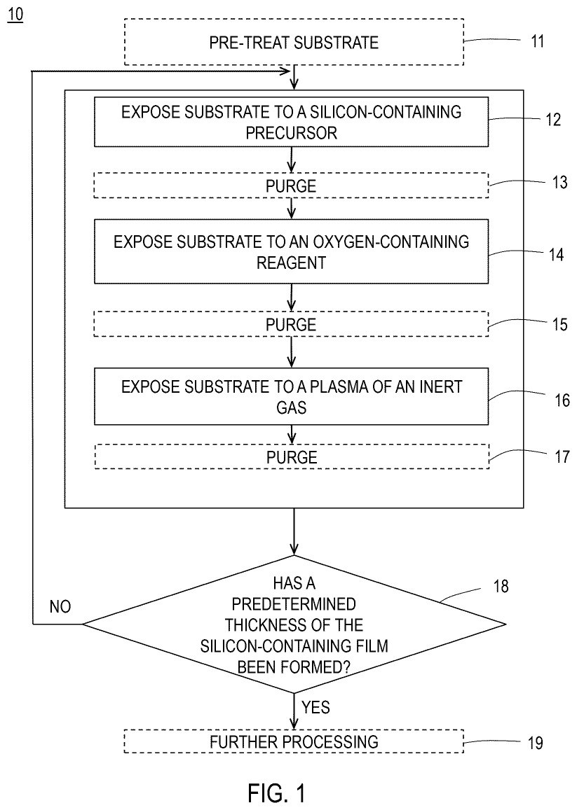

FIG. 1 illustrates a process flow diagram of a method 10 of depositing a silicon-containing film 200 on a substrate 102. The method 10 begins by optionally pre-treating the substrate 102 (operation 11). The pre-treatment can be any suitable pre-treatment known to the skilled artisan. Suitable pre-treatments include, but are not limited to, pre-heating, cleaning, soaking, or native oxide removal, as examples.

The method 10 of one or more embodiments comprises depositing the silicon-containing film 200 by PEALD. In one or more embodiments, the method 10 comprises exposing the substrate 102 to a silicon-containing precursor (operation 12); optionally purging the substrate 102 (operation 13); exposing the substrate 102 to an oxygen-containing reagent (operation 14); optionally purging the substrate 102 (operation 15); exposing the substrate 102 to a plasma of an inert gas (operation 16); and optionally purging the substrate 102 (operation 17). In one or more embodiments of FIG. 1, the dashed lines are used to denote that the stated operation is optional.

In some embodiments, the substrate 102 is exposed to the silicon-containing precursor at operation 12, followed by exposure to the oxygen-containing reagent at operation 14, followed by exposure to the plasma of the inert gas at operation 16.

In one or more embodiments, the method 10 is a PECVD process that comprises exposing the substrate 102 to a silicon-containing precursor (operation 12); exposing the substrate 102 to an oxygen-containing reagent (operation 14); and exposing the substrate 102 to a plasma of an inert gas (operation 16).

One or more of the exposures (e.g., the exposure to the silicon-containing precursor at operation 12, the exposure to the oxygen-containing reactant at operation 14, and the exposure to the plasma of the inert gas at operation 16) may occur simultaneously or substantially simultaneously. In some embodiments, each of the exposures (e.g., the exposure to the silicon-containing precursor at operation 12, the exposure to the oxygen-containing reactant at operation 14, and the exposure to the plasma of the inert gas at operation 16) occur simultaneously or substantially simultaneously.

In one or more embodiments, the substrate 102 is exposed to the silicon-containing precursor (operation 12) and the oxygen-containing reagent (operation 14) simultaneously or substantially simultaneously while the plasma of the inert gas (operation 16) is turned on. In one or more embodiments, the substrate 102 is exposed to the silicon-containing precursor (operation 12), followed by exposing the substrate 102 to the oxygen-containing reagent (operation 14) and the plasma of the inert gas (operation 16) simultaneously or substantially simultaneously.

In one or more embodiments, the substrate 102 is exposed to the silicon-containing precursor (operation 12) and the plasma of the inert gas (operation 16) simultaneously or substantially simultaneously, followed by exposing the substrate 102 to the oxygen-containing reagent (operation 14) and the plasma of the inert gas (operation 16) simultaneously or substantially simultaneously.

In one or more embodiments, the substrate 102 is exposed to the oxygen-containing reagent (operation 14) and the plasma of the inert gas (operation 16) simultaneously or substantially simultaneously, followed by exposing the substrate 102 to the silicon-containing precursor (operation 12) and the plasma of the inert gas (operation 16) simultaneously or substantially simultaneously.

In some embodiments, exposing the substrate 102 to the silicon-containing precursor at operation 12 and the oxygen-containing reagent at operation 14 comprises a thermal process. Stated differently, exposing the substrate 102 to the silicon-containing precursor at operation 12 and the oxygen-containing reagent at operation 14 is performed without the use of plasma. The method 10 comprises a plasma-enhanced atomic layer deposition (PEALD) process, and in accordance with one or more embodiments, the substrate 102 is exposed to a plasma (e.g., the plasma of the inert gas) beginning at operation 16. The PEALD process is a spatial PEALD process or a temporal PEALD process. In some embodiments, the PEALD process is a spatial PEALD process. In some embodiments, the PEALD process is a temporal PEALD process.

As will be described herein further below, one or more embodiments advantageously provide methods of depositing silicon-containing films with minimal change in resistivity of the underlying substrates, such as, for example, underlying metal substrates after the deposition process.

The method 10 continues to decision point 18. At decision point 18, the substrate 102 is evaluated to determine whether or not the silicon-containing film 200 has reached a predetermined thickness or a predetermined number of cycles have been performed. As used herein, each “cycle” refers to each iteration in which the method 10 is performed to deposit the silicon-containing film 200 to a predetermined thickness. If the conditions are met e.g., the answer to decision point 18 is “YES,” the method 10 continues to operation 19 for further processing. The skilled artisan will appreciate that that operation 19 can include one or more subsequent operations to form a device, such as device 100 as described herein, which can be performed without undue experimentation. If the conditions are not met, e.g., the answer to decision point 18 is “NO,” the method 10 returns to optional operation 11, or operation 12.

In one or more embodiments, the method 10 comprises, consists essentially of, or consists of operation 11, operation 12, operation 13, operation 14, operation 15, operation 16, operation 17, decision point 18, and operation 19.

One or more embodiments of the method 10 comprise repeating one or more operations of the method to deposit the silicon-containing film 200 to a predetermined thickness.

In one or more embodiments, operation 12, optional operation 13, operation 14, optional operation 15, operation 16, and optional operation 17, defines a process cycle. In one or more embodiments, the process cycle is repeated to deposit the silicon-containing film 200 to a predetermined thickness.

Some embodiments advantageously provide the ability to control the composition of the silicon-containing film 200 in accordance with the methods described herein. Some embodiments advantageously provide the ability to control the thickness of the silicon-containing film 200 to Angstrom-level accuracy in accordance with the methods described herein. Some embodiments advantageously provide the ability to control the step coverage, e.g., less than 100%, 100%, or greater than 100% of the silicon-containing film 200 in accordance with the methods described herein.

The silicon-containing film 200 comprises silicon atoms and one or more of carbon atoms, nitrogen atoms, and oxygen atoms. In some embodiments, the silicon-containing film 200 comprises, consists essentially of, or consists of silicon atoms, carbon atoms, nitrogen atoms, and oxygen atoms. In some embodiments, the silicon-containing film 200 comprises, consists essentially of, or consists of silicon atoms and carbon atoms. In some embodiments, the silicon-containing film 200 comprises, consists essentially of, or consists of silicon atoms and nitrogen atoms. In some embodiments, the silicon-containing film 200 comprises, consists essentially of, or consists of silicon atoms and oxygen atoms. In one or more embodiments, the silicon-containing film 200 comprises one or more of silicon nitride (SiN), silicon oxide (SiO₂), silicon carbonitride (SiCN), silicon oxycarbide (SiOC), or silicon carboxynitride (SiCON).

The silicon-containing precursor can be any suitable precursor that includes silicon. In some embodiments, the silicon-containing precursor has a general formula of SiRR¹R²R³ where R, R¹, R², and R³ are independently selected from H, CI, Br, I, NR′R″ where N is a nitrogen atom, R′ and R″ are independently selected from an alkyl group or an aryl group having in a range of from 1 to 8 carbon atoms. In some embodiments where the silicon-containing precursor has the general formula of SiRR¹R²R³, each of R, R¹, R², and R³ independently comprises H or NR′R″.

In some embodiments, the silicon-containing precursor includes, but is not limited to, one or more of a silane, a chlorosilane, or an iodosilane. In some embodiments, the silicon-containing precursor includes one or more of silane, disilane, trisilane, tetrasilane, chlorosilane, dichlorosilane, trichlorosilane, tetrachlorosilane, iodosilane, diiodosilane, triiodosilane, or tetraiodosilane. In some embodiments, the silicon-containing precursor includes bis(diethylamino)silane (BDEAS). In some embodiments, the silicon-containing precursor comprises hexachlorodisilane (HCDS).

In some embodiments, the silicon-containing precursor includes a siloxane having a general formula of R₃′—Si—O—Si—R₃″ where each R′ and R″ are independently selected from an alkyl group or an aryl group having in a range of from 1 to 8 carbon atoms. For the avoidance of doubt, there are three R′ groups bound to the first silicon and three R″ groups bound to the second silicon (after the oxygen atom) in the general formula of the siloxane. The backbone of the siloxane is “—Si—O—Si—”. In some embodiments, the silicon-containing precursor includes a silsesquioxane. In one or more embodiments, the silsesquioxane comprises one or more “—Si—O—Si—” siloxane backbone linkages and one or more tetrahedral silicon vertices.

It has been found that current PEALD approaches, e.g., exposure to silicon-containing precursor, purge, exposure to O₂/Ar plasma, purge, to form a silicon oxide (SiO₂) film, oxidizes the underlying substrate, which can be detrimental to device performance. Embodiments of the disclosure advantageously provide methods of depositing silicon-containing films, e.g., silicon oxide (SiO₂) films, substantially without oxidizing or without oxidizing, the underlying substrate. That is, in one or more embodiments, advantageously, the reaction of the silicon-containing precursor, the oxygen-containing reagent, and the plasma of the inert gas does not oxidize the underlying substrate. As described herein, an amount of substrate oxidation (Å) can be expressed as the average thickness of an oxide film in A on the substrate. In one or more embodiments, advantageously, the reaction of the silicon-containing precursor, the oxygen-containing reagent and the plasma of the inert gas in accordance with the methods described herein provides a reduced amount of oxidation of the underlying substrate compared to current PEALD approaches.

The oxygen-containing reagent comprises one or more of water, an alcohol, or an oxygen-containing organic group selected from the group consisting of an ether group, an ester group, an aldehyde group, a ketone group, an amide group, a carboxylic acid group, and an anhydride group. In some embodiments, the water comprises deoxygenated water. In some embodiments, the water comprises deionized water.

The alcohol has a general formula of R⁵—O—R⁶, where R⁵ and R⁶ are independently selected from H, an alkyl group, or an aryl group having in a range of from 1 to 12 carbon atoms. In one or more embodiments, the alcohol is ethanol. In one or more embodiments, the alcohol is tert-butanol.

The inert gas comprises argon (Ar), helium (He), nitrogen (N₂), xenon (Xe), or combinations thereof. In some embodiments, the inert gas comprises, consists essentially of, or consists of argon (Ar), helium (He), nitrogen (N₂), and xenon (Xe).

In some embodiments, the inert gas comprises, consists essentially of, or consists of argon (Ar). In some embodiments, the inert gas comprises, consists essentially of, or consists of helium (He). In some embodiments, the inert gas comprises, consists essentially of, or consists of nitrogen (N₂). In some embodiments, the inert gas comprises, consists essentially of, or consists of xenon (Xe).

In some embodiments, the inert gas comprises, consists essentially of, or consists of a combination of argon (Ar) and helium (He). In some embodiments, the inert gas comprises, consists essentially of, or consists of a combination of argon (Ar) and nitrogen (N₂). In some embodiments, the inert gas comprises, consists essentially of, or consists of a combination of argon (Ar) and xenon (Xe). In some embodiments, the inert gas comprises, consists essentially of, or consists of a combination of argon (Ar), helium (He), and nitrogen (N₂). In some embodiments, the inert gas comprises, consists essentially of, or consists of a combination of argon (Ar), helium (He), and xenon (Xe).

In some embodiments, the inert gas comprises, consists essentially of, or consists of a combination of helium (He) and nitrogen (N₂). In some embodiments, the inert gas comprises, consists essentially of, or consists of a combination of helium (He) and xenon (Xe). In some embodiments, the inert gas comprises, consists essentially of, or consists of a combination of helium (He), nitrogen (N₂), and xenon (Xe). In some embodiments, the inert gas comprises, consists essentially of, or consists of a combination of nitrogen (N₂) and xenon (Xe).

The plasma of the inert gas may be generated by any suitable plasma source. In one or more embodiments, a remote plasma source, an inductively coupled plasma (ICP) source, a capacitively coupled plasma (CCP) source, or a microwave plasma source may be used to generate the plasma of the inert gas.

The skilled artisan will appreciate that any remote plasma source, inductively coupled plasma (ICP) source, capacitively coupled plasma source (CCP) source, or microwave plasma source that is suitable for generating the plasma of the inert gas may be implemented for the disclosed methods. In one or more embodiments, the plasma source comprises an inductively coupled plasma (ICP) source or a capacitively coupled plasma (CCP) source. In one or more embodiments, the plasma source comprises an inductively coupled plasma (ICP) source. In one or more embodiments, the plasma source comprises a capacitively coupled plasma (CCP) source.

In one or more embodiments, the plasma of the inert gas is generated at a plasma power in a range of from 10 watts to 1000 watts.

During the deposition operations (e.g., exposing the substrate 102 to the silicon-containing precursor at operation 12, exposing the oxygen-containing reagent at operation 14, and exposing the substrate to the plasma of the inert gas at operation 16), an additional power source, such as a bias power source, may be engaged and coupled to provide a bias to the plasma (e.g., the plasma of the inert gas) generated above the substrate 102. The bias may draw plasma particles from the plasma of the inert gas to the substrate 102. The bias power applied may be relatively low to limit damage to a device including the silicon-containing film 200. Accordingly, in some embodiments a bias power source may deliver a plasma power of less than or about 1,000 watts and may deliver a power of less than or about 750 watts, less than or about 600 watts, less than or about 500 watts, less than or about 400 watts, or less. Additionally, by adjusting the plasma source power and the bias power applied, densification of the deposited silicon-containing film may occur during the deposition operation. In one or more embodiments, both the plasma power and the bias power may be applied.

In specific embodiments, the method 10 comprises exposing the substrate 102 to a silicon-containing precursor comprising hexachlorodisilane or bis(diethylamino)silane (operation 12); optionally purging the substrate 102 (operation 13); exposing the substrate 102 to an oxygen-containing reagent comprising water, ethanol, or tert-butanol (operation 14); optionally purging the substrate 102 (operation 15); exposing the substrate 102 to a plasma of an inert gas, e.g., argon (Ar) (operation 16); and optionally purging the substrate 102 (operation 17). In specific embodiments, when the oxygen-containing reagent comprises tert-butanol, the plasma comprising argon (Ar) is generated at a plasma pressure of 0.2 Torr and a plasma power of 100 watts. In specific embodiments, when the oxygen-containing reagent comprises ethanol, the plasma comprising argon (Ar) is generated at a plasma pressure of 2 Torr and a plasma power of 200 watts.

The method 10 may be performed at any suitable processing conditions, and the processing conditions may vary depending upon the application for which the silicon-containing film is formed.

In some embodiments, the method 10 is performed at relatively low temperatures. The relative low temperatures advantageously result in decreased damage to surrounding materials (e.g., dielectric materials). In some embodiments, the method 10 is performed at a temperature in the range of 20° C. to 600° C. Stated differently, “the method 10 is performed at a temperature in the range of 20° C. to 600° C.” means that the semiconductor processing system in which the method 10 is performed is maintained at a temperature in the range of 20° C. to 600° C. In some embodiments, the method 10 is performed at a temperature in the range of 100° C. to 600° C.

In some embodiments, the method 10 is performed at a pressure in a range of from 0.1 Torr to 500 Torr. Stated differently, “the method 10 is performed at a pressure in a range of from 0.1 Torr to 500 Torr” means that the semiconductor processing system in which the method 10 is performed is maintained at a pressure in a range of from 0.1 Torr to 500 Torr. In some embodiments, the method 10 is performed at a pressure in the range of 0.1 Torr to 100 Torr. In some embodiments, the method 10 is performed at a pressure in the range of 0.1 Torr to 10 Torr.

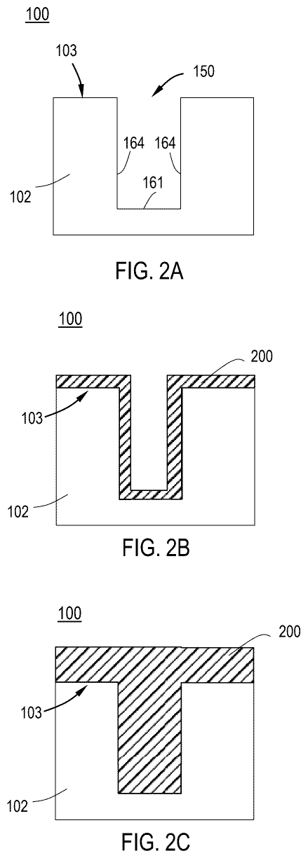

FIGS. 2A-2C illustrate cross-sectional schematic views of a device 100 including a substrate 102 according to one or more embodiments of the disclosure. The device 100 shown in FIGS. 2A-2C is generally representative of a semiconductor device or a microelectronic device. In specific embodiments, the device 100 shown in FIGS. 2A-2C is representative of a high aspect ratio structure, e.g., in memory devices or logic devices (at less than 10 nm technology nodes), including, but not limited to, NAND, 3D-NAND, dynamic random-access memory (DRAM) cells, 3D DRAM, Fin field effect transistors (FinFET), gate-all-around (GAA) transistors, and the like. In specific embodiments, the device 100 shown in FIGS. 2A-2C is representative of depositing the silicon-containing film 200 to fill the at least one feature 150 in a bottom-up fashion, such as for, as an example, shallow trench isolation (STI) applications.

The substrate 102 can be any suitable substrate material. In one or more embodiments, the substrate 102 comprises a semiconductor material, e.g., any metal material, silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), a high-K dielectric material other semiconductor materials, or any combination thereof. In one or more embodiments, the substrate 102 comprises one or more of silicon (Si), germanium (Ge), gallium (Ga), arsenic (As), indium (In), phosphorus (P), or selenium (Se).

In some embodiments, the substrate 102 includes one or more FEOL channel materials, such as, for example, gate contacts, silicon germanium (SiGe) and/or epi contacts). In some embodiments, the substrate 102 includes one or more BEOL metals, such as, for example, copper, cobalt, tungsten, molybdenum, ruthenium, tantalum, titanium, nitrides thereof, and/or alloys thereof.

Although a few examples of materials from which the substrate 102 may be made have been provided, any material that may serve as a foundation upon which passive and active electronic devices (e.g., transistors, memories, capacitors, inductors, resistors, switches, integrated circuits, amplifiers, optoelectronic devices, or any other electronic devices) can be utilized.

In some embodiments, the substrate 102 may include dielectric materials, for example, silicon-containing dielectric materials and/or metal oxide dielectric materials. In some embodiments, the substrate 102 may comprise one or more dielectric surfaces comprising a low-K dielectric material such as, but not limited to, silicon oxide (SiO₂), silicon sub-oxides, silicon nitride (SiN), silicon nitride (Si₃N₄), silicon carbide (SiC), silicon oxycarbide (SiOC), silicon carbonitride (SiCN), silicon oxynitride (SiON), or combinations thereof.

FIG. 2A illustrates the substrate 102 having a top surface 103 and including at least one feature 150 extending into the substrate 102. The at least one feature 150 has a bottom surface 161 and two sidewalls 164. In some embodiments, the bottom surface 161 comprises a metallic material. In some embodiments, the bottom surface 161 comprises a dielectric material. In some embodiments, the two sidewalls 164 comprise a dielectric material. In some embodiments, the two sidewalls 164 comprise a metallic material.

While the at least one feature 150 is shown extending vertically into the substrate 102, the skilled artisan will appreciate that disclosure is not limited to the illustrated embodiments, and that the at least one feature 150 can extend laterally within the substrate 102. In one or more embodiments, the substrate 102 having the at least one feature 150 includes one or more vertically extending features and one or more laterally extending features.

Embodiments of the disclosure advantageously provide methods of depositing silicon-containing films, e.g., silicon oxide (SiO₂) films, substantially without oxidizing or without oxidizing, the underlying substrate.

In one or more embodiments, as shown in FIG. 2B, the silicon-containing film 200 is deposited conformally on the top surface 103, along the two sidewalls 164, and on the bottom surface 161. In one or more embodiments, the bottom surface 161 comprises a BEOL metal, such as, for example, copper, cobalt, tungsten, molybdenum, ruthenium, tantalum, titanium, nitrides thereof, and/or alloys thereof. In one or more embodiments, the bottom surface 161 comprises one or more of silicon (Si) or silicon germanium (SiGe). Advantageously, in one or more embodiments, the silicon-containing film 200 is deposited conformally on the top surface 103, along the two sidewalls 164, and on the bottom surface 161 comprising the BEOL metal, without oxidizing the underlying substrate, e.g., without oxidizing the BEOL metal. Advantageously, in one or more embodiments, the silicon-containing film 200 is deposited conformally on the top surface 103, along the two sidewalls 164, and on the bottom surface 161 comprising one or more of silicon (Si) or silicon germanium (SiGe), without oxidizing the underlying substrate, e.g., without oxidizing the one or more of silicon (Si) or silicon germanium (SiGe).

In FIG. 2B, the silicon-containing film 200 is shown as conformally deposited on the top surface 103, along the two sidewalls 164, and on the bottom surface 161. Accordingly, FIG. 2B is an example of the silicon-containing film 200 having a step coverage of 100%.

It has been advantageously found that the conformality of the deposited silicon-containing film 200 is tunable based upon varying the plasma pressure and the plasma power. It has also been advantageously found that the conformality of the deposited silicon-oxide (SiO₂) film is tunable based upon varying the silicon-containing precursor. The conformality of the silicon-containing film 200 can range from greater than or equal to 1% to 100%. In one or more embodiments, the silicon-containing film 200 that is deposited in a bottom-up fashion is considered non-conformal, such as, for example a conformality of about 10%, or about 15%, or about 20%. Advantageously, the conformality of the silicon-containing film 200 can range from greater than or equal to 1% to 100%, such as, for example, in a range of from 10% to 90%, so that the silicon-containing film 200 can be used in varying applications.

It has advantageously been found, in one or more embodiments, that the growth of the silicon-containing film 200, e.g., the silicon oxide (SiO₂) film, in bottom-up fashion is highly ion-driven growth, with high temperature (400° C.), low plasma pressure (0.2 Torr), and high plasma power (200 watts) advantageously enhancing the bottom-up growth of the film.

In one or more embodiments, as shown in FIG. 2C, the silicon-containing film 200 is deposited to fill the at least one feature 150. It has been found that, in shallow trench isolation (STI) applications, for example, seams from sidewall growth negatively impact electrical performance. In one or more embodiments where the silicon-containing film 200 is deposited to fill the at least one feature 150, the silicon-containing film 200 is advantageously free of seams and/or voids.

In accordance with the method 10, at decision point 18, the substrate 102 is evaluated to determine whether or not the silicon-containing film 200 has reached a predetermined thickness or a predetermined number of cycles have been performed. In some embodiments, the silicon-containing film 200 has a thickness in a range of from about 0.1 Å to about 1000 Å.

In some embodiments, a silicon-containing film 200 is deposited on a dielectric surface with one or more high aspect ratio structures, including vertically extending features and/or laterally extending features, and the silicon-containing film 200 in the gap features forms interconnects through which current flows.

In one or more embodiments, the silicon-containing film 200 is deposited directly on a BEOL metal, such as, for example, copper, cobalt, tungsten, molybdenum, ruthenium, tantalum, titanium, nitrides thereof, and/or alloys thereof. In one or more embodiments, the silicon-containing film 200 is deposited directly on one or more of silicon (Si) or silicon germanium (SiGe). Advantageously, in one or more embodiments, the silicon-containing film 200 is deposited conformally on the top surface 103, along the two sidewalls 164, and on the bottom surface 161 comprising the BEOL metal, without oxidizing the underlying substrate, e.g., without oxidizing the BEOL metal. Advantageously, in one or more embodiments, the silicon-containing film 200 is deposited conformally on the top surface 103, along the two sidewalls 164, and on the bottom surface 161 comprising one or more of silicon (Si) or silicon germanium (SiGe), without oxidizing the underlying substrate, e.g., without oxidizing the one or more of silicon (Si) or silicon germanium (SiGe).

Advantageously, using the methods described herein, there is a minimal change in resistivity of the underlying substrates, such as, for example, underlying metal substrates after the deposition process. In some embodiments, it is thought that increasing the dose duration of tert-butanol, for example, can advantageously clean the underlying substrate, including, but not limited to one or more of the BEOL metal, silicon (Si), or silicon germanium (SiGe), for example, on which the silicon-containing film 200 is deposited on. In some embodiments, it is thought that increasing the dose duration of tert-butanol, for example, can advantageously provide lower resistivity by cleaning the one or more of the BEOL metal, silicon (Si), or silicon germanium (SiGe).

The methods described herein may be performed in any suitable processing system that includes a plasma chamber. In some embodiments, a suitable processing system comprises: a central transfer station comprising a robot configured to move a substrate or a plurality of substrates, a plurality of process stations, and a controller connected to the central transfer station and the plurality of process stations. In some embodiments, each process station is connected to the central transfer station and provides a processing region separated from processing regions of adjacent process stations. In some embodiments, the plurality of process stations comprises a plasma-enhanced chemical vapor deposition (PECVD) chamber. In some embodiments, the plurality of process stations comprises a plasma-enhanced atomic layer deposition (PEALD) chamber. In some embodiments, the controller is configured to activate the robot to move the substrate between process stations, and to control a processing method, such as method 10, and form a silicon-containing film, e.g., the silicon-containing film 200 on the substrate 102.

In some embodiments, one or more operations of the methods described herein, e.g., the method 10, are performed in situ. In some embodiments, each operation of the methods described herein, e.g., the method 10, is performed in situ. In some embodiments, one or more operations of the methods described herein, e.g., the method 10, are performed ex situ.

One or more embodiments of the disclosure are directed to a non-transitory computer readable medium including instructions, that, when executed by a controller of a processing system, cause the processing system to perform the operations of the methods described herein, e.g., the method 10.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Comparative Example 1

A silicon oxide (SiO₂) film was deposited by plasma-enhanced atomic layer deposition (PEALD) by exposing a silicon substrate to: bis(diethylamino)silane (BDEAS), purge gas, a plasma comprising oxygen (O₂) and argon (Ar), and purge gas.

In some experiments, the plasma was generated by a capacitively coupled plasma (CCP) source. In some experiments, the plasma comprised a 1:1 ratio of O₂:Ar.

In an experiment, the silicon oxide (SiO₂) film was measured using Fourier Transform Infrared Spectroscopy (FTIR) to determine whether the film had “silicon oxide (SiO₂) character” or “silicon carboxynitride (SiCON) character.” It has been found that a peak in the FTIR shifting toward 1000 cm⁻¹ resembles silicon carboxynitride (SiCON) character and a peak shifting toward 1060 cm⁻¹ resembles silicon oxide (SiO₂) character.

In one experiment, exposing the substrate to the plasma comprising oxygen (O₂) and argon (Ar) was performed at a pressure of 1 Torr and a plasma power of 200 watts with a 10-second plasma dosing period. The frequency of the FTIR peak for the silicon oxide (SiO₂) film was about 1062 cm⁻¹, demonstrating silicon oxide (SiO₂) character.

### Inventive Example 1

A silicon oxide (SiO₂) film was deposited by plasma-enhanced atomic layer deposition (PEALD) in accordance with the present disclosure by exposing a silicon substrate to: bis(diethylamino)silane (BDEAS), purge gas, ethanol, purge gas, a plasma comprising argon (Ar), and purge gas.

The wet etch rate (WER) of the silicon oxide (SiO₂) film was measured under dilute hydrofluoric (HF) acid etch solution dilute HF 100:1 in various experiments. In each of the experiments described herein with respect to Inventive Example 1, the PEALD process was performed at a temperature of 400° C., the substrate was exposed to BDEAS for 0.3 seconds.

In one experiment, the substrate was exposed to ethanol for a 1 second exposure period and a 30 second soak period, and the substrate was exposed to the plasma comprising argon (Ar) (generated at a plasma pressure of 10 Torr and a plasma power of 200 watts) for 10 seconds. In the experiment where the substrate was exposed to ethanol for a 1 second exposure period and a 30 second soak period, The wet etch rate ratio (WERR) relative to that of thermal silicon dioxide, having a wet etch rate of about 25 Å/min, of the silicon-containing film was 83. The composition of the silicon-containing film and the growth per cycle (GPC) of the silicon-containing film were also measured. In the experiment where the substrate was exposed to ethanol for a 1 second exposure period and a 30 second soak period, the silicon-containing film included 29.1 at. % silicon, 62.7 at. % oxygen, 5.1 at. % carbon, and 3.1 at. % nitrogen. The GPC was about 0.16 Å/cycle.

In another experiment, the substrate was exposed to ethanol for a 0.2 seconds exposure period and no soak period, and the substrate was exposed to the plasma comprising argon (Ar) (generated at a plasma pressure of 2 Torr and a plasma power of 200 watts) for 10 seconds. In the experiment where the substrate was exposed to ethanol for a 0.2 seconds exposure period and no soak period, the wet etch rate ratio (WERR) relative to that of thermal silicon dioxide, having a wet etch rate of about 25 Å/min, of the silicon-containing film was 3.3. The composition of the silicon-containing film and the growth per cycle (GPC) of the silicon-containing film were also measured. In the experiment where the substrate was exposed to ethanol for a 0.2 seconds exposure period and no soak, the silicon-containing film included 27.0 at. % silicon, 46.1 at. % oxygen, 15.5 at. % carbon, and 9.4 at. % nitrogen. The GPC was about 0.16 Å/cycle.

In another experiment, the substrate was not exposed to ethanol. That is, in one experiment, the substrate was exposed to BDEAS and the plasma comprising argon (Ar). In the experiment where the substrate was not exposed to ethanol, the wet etch rate ratio (WERR) relative to that of thermal silicon dioxide, having a wet etch rate of about 25 Å/min, of the silicon-containing film was 116. The composition of the silicon-containing film was also measured. In the experiment where the substrate was not exposed to ethanol, the silicon-containing film included 28.4 at. % silicon, 42.3 at. % oxygen, 7.7 at. % carbon, and 21.6 at. % nitrogen.

In view of these experiments, it has been found that the growth per cycle (GPC) did not change with duration of the ethanol exposure. The duration of the ethanol exposure did show changes in the composition of the silicon-containing film. In particular, it has been found that the shorter ethanol exposure period (0.2 seconds compared to 1 second, described above in this section) resulted in the silicon-containing film having, by at. %, less silicon, less oxygen, more carbon, and more nitrogen.

In one experiment, the silicon oxide (SiO₂) film was formed by exposing the substrate to BDEAS, then ethanol for 1 second at a pressure of 10 Torr, with a soaking period of 30 seconds, followed by the plasma comprising argon (Ar) for a duration of 10 seconds at a plasma pressure of 2 Torr and a plasma power of 200 watts. The frequency of the FTIR peak for the silicon oxide (SiO₂) film was about 1046 cm⁻¹, demonstrating silicon oxide (SiO₂) character.

In another experiment, the film was formed by exposing the substrate to BDEAS, then ethanol for 0.2 seconds at a pressure of 2 Torr with no soaking period, followed by the plasma comprising argon (Ar) for a duration of 10 seconds at a plasma pressure of 2 Torr and a plasma power of 200 watts. The frequency of the FTIR peak for the film was about 1014 cm⁻¹, demonstrating silicon carboxynitride (SiCON) character.

In another experiment, the film was formed by exposing the substrate to BDEAS, followed by the plasma comprising argon (Ar) for a duration of 10 seconds at a plasma pressure of 2 Torr and a plasma power of 200 watts. In this experiment, an oxygen-containing reagent was not used to form the film. The frequency of the FTIR peak for the film was about 987 cm⁻¹, demonstrating silicon carboxynitride (SiCON) character.

The deposited film was measured using Fourier Transform Infrared Spectroscopy (FTIR) at varying processing conditions in further experiments, as described below in Table 2.

### Inventive Example 2

A silicon oxide (SiO₂) film was deposited by plasma-enhanced atomic layer deposition (PEALD) in accordance with the present disclosure by exposing a silicon substrate to: bis(diethylamino)silane (BDEAS), purge gas, tert-butanol, purge gas, a plasma comprising argon (Ar), and purge gas.

Advantageously, there was less substrate oxidation in each of Inventive Example 1 and Inventive Example 2 as compared to the silicon oxide (SiO₂) film deposited in Comparative Example 1.

In particular, it has been advantageously found that the plasma comprising oxygen (O₂) and argon (Ar) of Comparative Example 1 produces a greater percentage of silicon oxidation than an alcohol, such as ethanol (Inventive Example 1) or tert-butanol (Inventive Example 2) with a plasma comprising argon (Ar).

It has been advantageously found that the conformality of the deposited silicon-oxide (SiO₂) film is tunable based upon varying the plasma pressure and the plasma power. It has also been advantageously found that the conformality of the deposited silicon-oxide (SiO₂) film is tunable based upon varying the silicon-containing precursor. The conformality of the silicon-oxide (SiO₂) film can range from greater than or equal to 1% to 100%. In each experiment of Table 1, the silicon oxide (SiO₂) film was deposited in a feature having a top surface, a bottom surface, and two sidewalls in a bottom-up fashion to a thickness in a range of from 50 Å to 200 Å.

TABLE 1
Conformality Based Upon Plasma Pressure and Plasma Power
Inventive Example 2 (BDEAS, tert-butanol, Ar plasma)

| Plasma | | Plasma | GPC | Conform- | Conformality |
|---|---|---|---|---|---|
| Pressure | | Power | (Å/cycle) | ality % | Ratio T:B:S |
| 0.5 | Torr | 100 watts | 0.46 | 89 | 1:0.89:0.97 |
| 0.5 | Torr | 200 watts | 0.93 | 45 | 1:0.45:0.47 |
| 2 | Torr | 200 watts | 0.21 | 87 | 0.86:0.87:1 |

For each experiment in Table 1, the Conformality Ratio is expressed as top surface (T) to bottom surface (B) to two sidewalls(S): T:B:S.

The data in Table 1 exhibits that higher plasma power and lower plasma pressure generally produces higher numbers of ions in the plasma. The data in Table 1 advantageously exhibits that the conformality in the deposited film is tunable: lower plasma pressure with higher plasma power yields lower conformality, and higher plasma pressure with lower plasma power yields higher conformality.

TABLE 2
Comparing “SiO₂ Character” vs. “SiCON Character”
for Inventive Example 1 and Inventive Example 2

| | | |
|---|---|---|
| Plasma | Plasma | |
| Pressure | Power | FTIR Results |

Inventive Example 1 (BDEAS, Ethanol, Ar plasma)

| | | | |
|---|---|---|---|
| 0.5 | Torr | 100 watts | 1012 cm⁻¹ |
| | | | SiCON Character |
| 2 | Torr | 100 watts | 1040 cm⁻¹ |
| | | | SiO₂ Character |
| 2 | Torr | 200 watts | 1050 cm⁻¹ |
| | | | SiO₂ Character |
| | | | WERR (3.5) compared to |
| | | | thermal silicon dioxide wet |
| | | | etch rate.* |
| | | | *The wet retch rate of the |
| | | | deposited film was 3.5 times |
| | | | as fast as that of thermal |
| | | | silicon dioxide. |

Inventive Example 2 (BDEAS, tert-butanol, Ar plasma)

| | | | |
|---|---|---|---|
| 0.5 | Torr | 100 watts | 1030 cm⁻¹ |
| | | | SiO₂ Character |
| | | | WERR (3.4) compared to |
| | | | thermal silicon dioxide wet |
| | | | etch rate.* |
| | | | *The wet retch rate of the |
| | | | deposited film was 3.4 times |
| | | | as fast as that of thermal |
| | | | silicon dioxide. |
| 0.5 | Torr | 200 watts | 1029 cm⁻¹ |
| | | | SiO₂ Character |
| | | | WERR (2.6) compared to |
| | | | thermal silicon dioxide wet |
| | | | etch rate.* |
| | | | *The wet retch rate of the |
| | | | deposited film was 2.6 times |
| | | | as fast as that of thermal |
| | | | silicon dioxide. |
| 2 | Torr | 200 watts | 1005 cm⁻¹ |
| | | | SiCON Character |
| | | | WERR (6.5) compared to |
| | | | thermal silicon dioxide wet |
| | | | etch rate.* |
| | | | *The wet retch rate of the |
| | | | deposited film was 6.5 times |
| | | | as fast as that of thermal |
| | | | silicon dioxide. |

In each experiment detailed in Table 2, the silicon oxide (SiO₂) film was measured using Fourier Transform Infrared Spectroscopy (FTIR) to determine whether the deposited film had silicon oxide (SiO₂) character or silicon carboxynitride (SiCON) character.

Accordingly, in view of the Comparative Example 1 and Inventive Examples 1 and 2, to produce films demonstrating silicon oxide (SiO₂) character, it has been found that a larger alcohol dose is needed. It has also been found that silicon carboxynitride (SiCON) character was observed with low alcohol dose and/or no alcohol dose.

As shown in Table 2, it has been found that when the oxygen-containing reagent comprises ethanol, a higher plasma pressure for the plasma comprising argon (Ar) (e.g., 2 Torr) demonstrates silicon oxide (SiO₂) character. It has been found that when the oxygen-containing reagent comprises tert-butanol, a lower plasma pressure for the plasma comprising argon (Ar) (e.g., 0.5 Torr) demonstrates silicon oxide (SiO₂) character.

TABLE 3
Comparing Plasma Dose Dependence for Inventive
Example 1 and Inventive Example 2

| | | |
|---|---|---|
| Plasma | | GPC |
| Dose Duration | FTIR Results | (Å/cycle) |

Inventive Example 1 (BDEAS, Ethanol, Ar plasma)

| | | |
|---|---|---|
| 5 seconds | 1024 cm⁻¹ | 0.27 |
| | SiCON Character | |
| 10 seconds | 1030 cm⁻¹ | 0.46 |
| | SiO₂ Character | |

Inventive Example 2 (BDEAS, tert-butanol, Ar plasma)

| | | |
|---|---|---|
| 5 seconds | 1006 cm⁻¹ | 0.10 |
| | SiCON Character | |
| 10 Seconds | 1050 cm⁻¹ | 0.17 |
| | SiO₂ Character | |

In experiments involving Inventive Example 1, the process was performed a temperature of 400° C., with a plasma pressure of 2 Torr and a plasma power of 200 watts.

In experiments involving Inventive Example 2, the process was performed a temperature of 400° C., with a plasma pressure of 0.5 Torr and a plasma power of 100 watts.

The shorter plasma dose duration exhibits reduced GPC in experiments involving Inventive Example 1 and Inventive Example 2. The data in Table 3 suggests reduced removal/incomplete reaction of surface-bound alcohol with the plasma comprising argon (Ar). The data in Table 3 also suggests increased plasma dose duration could improve SiO₂-like quality in other process regimes.

### Inventive Example 3

A silicon oxide (SiO₂) film was deposited by plasma-enhanced atomic layer deposition (PEALD) in accordance with the present disclosure by exposing a silicon substrate to: bis(diethylamino)silane (BDEAS), purge gas, water, purging, a plasma comprising argon (Ar), and purge gas.

In one experiment, exposing the substrate to the plasma comprising argon (Ar) was performed at a pressure of 2 Torr and a plasma power of 200 watts with a 20-second plasma dosing period. The frequency of the FTIR peak for the silicon oxide (SiO₂) film was about 1054 cm⁻¹, demonstrating silicon oxide (SiO₂) character.

### Inventive Example 4

A silicon oxide (SiO₂) film was deposited by plasma-enhanced atomic layer deposition (PEALD) in accordance with the present disclosure by exposing a silicon substrate to: hexachlorodisilane (HCDS), purge gas, ethanol, purge gas, a plasma comprising argon (Ar), and purge gas.

### Inventive Example 5

A silicon oxide (SiO₂) film was deposited by plasma-enhanced atomic layer deposition (PEALD) in accordance with the present disclosure by exposing a silicon substrate to: hexachlorodisilane (HCDS), purge gas, tert-butanol, purge gas, a plasma comprising argon (Ar), and purging.

In each of the experiments described herein with respect to Inventive Example 5, the PEALD process was performed at a temperature of 400° C., the substrate was exposed to HCDS for 0.3 seconds, a plasma pressure of 0.2 Torr, and a plasma power of 200 watts.

In a first experiment, the silicon oxide (SiO₂) film was deposited in a feature having a top surface, a bottom surface, and two sidewalls in a bottom-up fashion to a thickness of 50 Å. The feature had a top opening having a greater width of the opening at the bottom of the feature, e.g., the bottom opening. The feature had a width of about 100 nm at the top opening with a v-shape down to the bottom surface, the bottom opening having a width of about 25 nm. In this experiment, the silicon oxide (SiO₂) film had a conformality of about 20%. The ratio of the thickness of the film on the top surface (T) to bottom surface (B) to two sidewalls(S) (T:B:S) was about 1:0.2:0.24.

In a second experiment, the silicon oxide (SiO₂) film was deposited in a feature having a top surface, a bottom surface, and two sidewalls in a bottom-up fashion to a thickness of 50 Å. The feature had a top opening having a greater width of the opening at the bottom of the feature, e.g., the bottom opening. The feature had a width of about 200 nm at the top opening with a v-shape down to the bottom, the bottom having a width of about 50 nm. In this experiment, the silicon oxide (SiO₂) film had a conformality of about 37%. The ratio of the thickness of the film on the top surface (T) to bottom surface (B) to two sidewalls(S) (T:B:S) was about 1:0.37:0.42.

In each of the first experiment and the second experiment, the frequency of the FTIR peak for the silicon oxide (SiO₂) film was about 1059 cm⁻¹, demonstrating silicon oxide (SiO₂) character. The wet etch rate ratio (WERR) relative to that of thermal silicon dioxide, having a wet etch rate of about 25 Å/min, of the silicon-containing film in each of the first experiment and the second experiment was about 96.

The first experiment and the second experiment suggest that the growth of the silicon oxide (SiO₂) film in bottom-up fashion is highly ion-driven growth, with high temperature (400° C.), low plasma pressure (0.2 Torr), and high plasma power (200 watts) advantageously enhancing the bottom-up growth of the film.

Further to the above, with respect to Table 1, it has been advantageously found that the conformality of the deposited silicon-oxide (SiO₂) film is tunable based upon varying the plasma pressure and the plasma power. It has also been advantageously found that the conformality of the deposited silicon-oxide (SiO₂) film is tunable based upon varying the silicon-containing precursor. The data of Table 1 refers to Inventive Example 2 (BDEAS, tert-butanol, Ar plasma). Table 4 advantageously provides evidence of tunable conformality based upon different PEALD processes.

In each experiment of Table 4, the silicon oxide (SiO₂) film was deposited in a feature having a top surface, a bottom surface, and two sidewalls in a bottom-up fashion to a thickness in a range of from 50 Å to 200 Å at a temperature of 400° C., a plasma pressure of 2 Torr, and a plasma power of 200 watts.

TABLE 4
Conformality Based Upon Plasma Pressure and Plasma Power

| | | | | | | WERR |
|---|---|---|---|---|---|---|
| | | | | | | relative |
| | | | | | | to that |
| | | | | X-ray | | of |
| | | | | photoelectron | | thermal |
| | GPC | Conformality | Conformality | spectroscopy | FTIR | silicon |
| Example | (Å/cycle) | % | Ratio T:B:S | (XPS) Data | Results | dioxide |
| Comparative | 1.4 | 61 | 1:0.61:0.61 | Si - 33.6 at. % | 1060 cm⁻¹ | 1.2 |
| Example 1 | | | | O - 66.3 at. % | SiO₂ | |
| (BDEAS + | | | | C - 0.1 at. % | Character | |
| O₂/Ar | | | | N - 0.0 at. % | | |
| plasma) | | | | Cl - 0.0 at. % | | |
| Inventive | 1.4 | 12 | 1:0.12:0.18 | Si - 31.5 at. % | 1033 cm⁻¹ | 0.57 |
| Example 4 | | | | O - 59.8 at. % | SiO₂ | |
| (HCDS, | | | | C - 4.3 at. % | Character | |
| Ethanol, Ar | | | | N - 3.2 at. % | | |
| plasma) | | | | Cl - 1.2 at. % | | |
| Inventive | 0.95 | 20 | 1:0.2:0.24 | Si - 32.8 at. % | 1059 cm⁻¹ | 0.96 |
| Example 5 | | | | O - 67.2 at. % | SiO₂ | |
| (HCDS, tert- | | | | C - 0.0 at. % | Character | |
| butanol, Ar | | | | N - 0.0 at. % | | |
| plasma) | | | | Cl - 0.0 at. % | | |
| Inventive | 2.0 | 36 | 1:0.36:0.42 | Si - 32.8 at. % | 1038 cm⁻¹ | 1.6 |
| Example 2 | | | | O - 62.0 at. % | SiO₂ | |
| (BDEAS, | | | | C - 2.6 at. % | Character | |
| tert-butanol, | | | | N - 2.6 at. % | | |
| Ar plasma) | | | | Cl - 0.0 at. % | | |

For each experiment in Table 4, the Conformality Ratio is expressed as top surface (T) to bottom surface (B) to two sidewalls(S): T:B:S.

The PEALD process including HCDS as the silicon-containing precursor has the highest non-conformality as shown in Table 4 and can be used in a reactive-ion deposition (RID) process.

TABLE 5
Amount of Substrate Oxidation

| | | | Amount of |
|---|---|---|---|
| | | | Substrate |
| | | GPC | Oxidation |
| Example | Plasma Conditions | (Å/cycle) | (Å) |
| Comparative | Plasma Pressure: 2 Torr | 0.75 | 9.9 |
| Example | Plasma Power: 200 watts | | |
| 1 (BDEAS + | | | |
| O₂/Ar plasma) | | | |
| Comparative | Plasma Pressure: 0.2 Torr | 1.4 | 31.0 |
| Example | Plasma Power: 200 watts | | |
| 1 (BDEAS + | | | |
| O₂/Ar plasma) | | | |
| Inventive Example | Plasma Pressure: 0.2 Torr | 1.1 | 7.6 |
| 5 (HCDS, tert- | Plasma Power: 200 watts | | |
| butanol, Ar plasma) | | | |
| Inventive Example | Plasma Pressure: 0.2 Torr | 1.7 | 5.9 |
| 2 (BDEAS, tert- | Plasma Power: 200 watts | | |
| butanol, Ar plasma) | | | |
| Inventive Example | Plasma Pressure: 2 Torr | 0.39 | 1.2 |
| 3 (BDEAS, water, | Plasma Power: 200 watts | | |
| Ar plasma) | | | |
| Inventive Example | Plasma Pressure: 2 Torr | 0.32 | 1.1 |
| 1 (BDEAS, ethanol, | Plasma Power: 200 watts | | |
| Ar plasma) | | | |

In Table 5, each Example was performed for 25, 50, and 100 cycles on silicon (Si) substrates and silicon germanium (SiGe) substrates, respectively. The Amount of Substrate Oxidation (Å) is expressed as the average thickness of an oxide film in Å on the substrate, either the silicon (Si) substrates or the silicon germanium (SiGe) substrates. Advantageously, the PEALD process in accordance with one or more embodiments, e.g., described with respect to the Inventive Examples, demonstrates substantially less substrate oxidation compared to current PEALD approaches, e.g. Comparative Example 1.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of depositing a silicon-containing film, the method comprising:
exposing a substrate in a processing system to a silicon-containing precursor;
exposing the substrate to an oxygen-containing reagent; and
exposing the substrate to a plasma of an inert gas, wherein exposing the substrate to the silicon-containing precursor and exposing the substrate to the oxygen-containing reagent are each performed without the use of plasma.

2. The method of claim 1, comprising repeating one or more operations of the method to deposit the silicon-containing film to a predetermined thickness.

3. The method of claim 1, wherein the silicon-containing precursor has a general formula of SiRR¹R²R³ where R, R¹, R², and R³ are independently selected from H, CI, Br, I, NR′R″ where N is a nitrogen atom, R′ and R″ are independently selected from an alkyl group or an aryl group having in a range of from 1 to 8 carbon atoms.

4. The method of claim 1, wherein the silicon-containing precursor comprises a disilane, a trisilane, a tetrasilane, a siloxane having a general formula of R₃′—Si—O—Si—R₃″ where each R′ and R″ are independently selected from an alkyl group or an aryl group having in a range of from 1 to 8 carbon atoms, or a silsesquioxane.

5. The method of claim 1, wherein the oxygen-containing reagent comprises one or more of water, an alcohol, or an oxygen-containing organic group selected from the group consisting of an ether group, an ester group, an aldehyde group, a ketone group, an amide group, a carboxylic acid group, and an anhydride group.

6. The method of claim 5, wherein the alcohol has a general formula of R⁵—O—R⁶, where R⁵ and R⁶ are independently selected from H, an alkyl group, or an aryl group having in a range of from 1 to 12 carbon atoms.

7. The method of claim 1, wherein the plasma of the inert gas is generated by a plasma source comprising one or more of a remote plasma source, an inductively coupled plasma (ICP) source, a capacitively coupled plasma (CCP) source, or a microwave plasma source.

8. The method of claim 7, wherein the plasma source comprises an inductively coupled plasma (ICP) source or a capacitively coupled plasma (CCP) source.

9. The method of claim 7, wherein the plasma of the inert gas is generated at a plasma pressure in a range of from 0.1 Torr to 500 Torr.

10. The method of claim 7, wherein the plasma of the inert gas is generated at a plasma power in a range of from 10 watts to 1000 watts.

11. The method of claim 1, wherein the inert gas comprises argon (Ar), helium (He), nitrogen (N₂), xenon (Xe), or combinations thereof.

12. The method of claim 1, wherein the substrate comprises at least one feature having a bottom surface and two sidewalls.

13. The method of claim 12, wherein the at least one feature has an aspect ratio in a range of 1:1 to 100:1.

14. The method of claim 12, wherein the silicon-containing film is deposited to fill the at least one feature in a bottom-up fashion.

15. The method of claim 1, wherein the silicon-containing film is deposited without oxidizing the substrate.

16. The method of claim 1, wherein the silicon-containing film comprises silicon atoms and one or more of carbon atoms, nitrogen atoms, and oxygen atoms.

17. The method of claim 1, performed at a temperature in a range of from 20° C. to 600° C.

18. A method of depositing a silicon-containing film, the method comprising:
exposing a substrate in a processing system to a silicon-containing precursor comprising hexachlorodisilane or bis(diethylamino)silane;
exposing the substrate to an oxygen-containing reagent comprising water, ethanol, or tert-butanol; and
exposing the substrate to a plasma comprising argon (Ar), wherein exposing the substrate to the silicon-containing precursor and exposing the substrate to the oxygen-containing reagent are each performed without the use of plasma, the substrate comprises at least one feature having a bottom surface and two sidewalls, the at least one feature has an aspect ratio in a range of 1:1 to 100:1, and the silicon-containing film is deposited to fill the at least one feature in a bottom-up fashion.

19. The method of claim 18, wherein when the oxygen-containing reagent comprises tert-butanol, the plasma comprising argon (Ar) is generated at a plasma pressure of 0.2 Torr and a plasma power of 100 watts.

20. The method of claim 18, wherein when the oxygen-containing reagent comprises ethanol, the plasma comprising argon (Ar) is generated at a plasma pressure of 2 Torr and a plasma power of 200 watts.
